(19) United States
(12) Patent Application Publication
(10) Pub. No.: US 2019/0207034 A1
(43) Pub. Date: Jul. 4, 2019

(54) Split-Gate Memory Cell With Field-Enhanced Source Junctions, And Method Of Forming Such Memory Cell

(71) Applicant: Microchip Technology Incorporated, Chandler, AZ (US)

(72) Inventors: Sonu Daryanani, Tempe, AZ (US); James Walls, Mesa, AZ (US); Sajid Kabeer, Tempe, AZ (US)

(73) Assignee: Microchip Technology Incorporated, Chandler, AZ (US)

(21) Appl. No.: 15/955,251

(22) Filed: Apr. 17, 2018

Related U.S. Application Data
(60) Provisional application No. 62/611,012, filed on Dec. 28, 2017.

(51) Int. Cl. H01L 29/788; H01L 27/11521; H01L 29/66; H01L 21/265; H01L 21/324; H01L 21/225; H01L 29/167

(52) U.S. Cl. CPC H01L 29/7884; H01L 27/11521; H01L 29/66825; H01L 29/167; H01L 21/324; H01L 21/2253; H01L 21/26513

(57) ABSTRACT

A method is provided for forming a split-gate memory cell having field enhancement regions in the substrate for improved cell performance. The method may include forming a pair of gate structures over a substrate, performing a source implant between the pair of gate structures to form a self-aligned source implant region in the substrate, performing a field enhancement implant process to form field enhancement implant regions, e.g., having an opposite dopant polarity as the source implant, at or adjacent lateral sides of the source implant region, and diffusing the source implant region and field enhancement implant regions to thereby define a source region with field enhanced regions at lateral edges of the source region. The field enhanced implant process may include at least one non-vertical angled implant.

### RELATED PATENT APPLICATION

This application claims priority to commonly owned U.S. Provisional Patent Application No. 62/611,012 filed Dec. 28, 2017, which is hereby incorporated by reference herein for all purposes.

### TECHNICAL FIELD

The present disclosure relates to split-gate memory cells, and more particularly, a split-gate memory cell having field-enhanced source junctions for improved cell performance, and methods for forming such split-gate memory cell.

### BACKGROUND

FIG. 1A illustrates a partially formed split-gate flash memory cell 100, according to a conventional process. As shown, a pair of floating gates 104 with an overlying “football” oxide region 105 are formed over a substrate 102, and a Poly2 wordline 110 may be formed over each floating gate 104. A vertical source implant, e.g., a high-voltage ion implant (HVII), is performed between the floating gates 104, to define a source implant region 106A having self-aligned edge junctions. In some implementations, a photoresist mask 108 may be formed prior to the source implant, to contain the effected region.

FIG. 1B illustrates the example split-gate flash memory cell 100 of FIG. 1A, after performing an anneal process that causes a diffusion of the source implant region 106A within the substrate 102, to define the final source region 106B. The memory cell 100 may be further processed, e.g., by forming bitline junctions 120 and corresponding bitline contacts 122, along with wordline contacts 112 over the Poly2 wordlines 110, for example.

This conventional split-gate flash memory cell 100 may be programmed by applying defined voltages to the source 106B, bitline contacts 122, and wordline contacts 112 for a defined programming time to provide a threshold cell current that corresponds with a programmed state of the cell. Example voltages are shown in FIG. 1B, including a voltage of ˜9.5V applied to the source region 106B for a defined time to achieve a threshold cell current corresponding with a programmed state.

As known in the art, a typical split-gate flash memory cell uses hot electron injection (“HEI”) to program the cell. The programming overhead such as the source line charge pumps can be a significant overhead in the total flash panel size. In addition, the total programming time per bit or the depth to which the programming is performed can create burdens on either the total program time for customers and/or the test time.

### SUMMARY

Embodiments of the present disclosure provide an improved split-gate memory cell and methods for forming an improved split-gate memory cell. In particular, some embodiments provide a split-gate memory cell having field-enhanced source junctions for improved cell performance, and methods for forming such split-gate memory cell. The field-enhanced source junctions may be formed by performing a field enhancement implant (e.g., boron) in the substrate proximate the lateral edges of the source region to create a more abrupt junction between the source region (e.g., phosphorus-doped) and the adjacent substrate (e.g., boron-doped), which increases the field energy resulting from a particular voltage. The field enhanced implant process may include at least one non-vertical angled implant having an opposite polarity as the source implant. As a result of the field-enhanced source junctions, the memory cell may be programmed using a lower voltage or lower programming time to achieve a defined cell current corresponding to a programmed state, as compared with conventional cells. Thus, embodiments of the invention may increase the operational efficiency of the memory cell.

### BRIEF DESCRIPTION OF THE DRAWINGS

Example aspects of the present disclosure are described below in conjunction with the figures, in which:

FIG. 1A illustrates an example source implant for a split-gate flash memory cell, according to a conventional process;

FIG. 1B illustrates the example split-gate memory cell of FIG. 1A after diffusion of the source implant region and further processing of the cell, and illustrates example voltage conditions for performing a program operation in the cell, according to conventional techniques;

FIG. 2A illustrates a source implant for an example split-gate flash memory cell, along with field enhancement implants that form field enhancement implant regions near lateral edges of the source implant region in the substrate, according to an example embodiment of the present invention;

FIG. 2B illustrates the example split-gate memory cell of FIG. 2B after diffusion of the source implant region and field enhancement implant regions that defines field-enhanced junctions at the lateral edges of the source region, and illustrates example voltage conditions for performing a program operation in the cell, according to an example embodiment of the present invention;

FIG. 3 illustrates an example process flow for producing a split-gate flash memory cell, e.g., the example cell shown in FIGS. 2A-2B, according to an example embodiment of the present invention;

FIG. 4 illustrates example dopant profile simulations at the source junction edge for (a) a conventional memory cell and (b) a memory cell formed according to the present invention (e.g., using field enhancement implants to provide field-enhanced source junction edges);

FIG. 5 is a graph illustrating the relationship between field junction doping concentration (e.g., substrate doping concentration at the source edge junction) and resulting electric field in a memory cell, for various example program voltage levels applied to the cell, which illustrates that an increase in field junction doping concentration allows a reduction in the required program voltage for the cell; and

FIG. 6 illustrates example graphs of programming time versus resulting cell current for (a) a pair of bit cells of a conventional split-gate memory cell (e.g., as shown in FIG. 1B) and (b) a pair of bit cells of an example split-gate memory cell formed according to the present invention (e.g., as shown in FIG. 2B), which illustrates that the memory cell formed according to the present invention allows a reduced programming time to achieve a target cell current.

### DETAILED DESCRIPTION

Embodiments of the present disclosure provide an improved split-gate memory cell and methods for forming an improved split-gate memory cell. In particular, some embodiments provide a split-gate memory cell having field-enhanced source junctions for improved cell performance, and methods for forming such split-gate memory cell. The field-enhanced source junctions may be formed by performing a field enhancement implant (e.g., boron) in the substrate proximate the lateral edges of the source region to create a more abrupt junction between the source region (e.g., phosphorus-doped) and the adjacent substrate (e.g., boron-doped), which increases the field energy resulting from a particular voltage. As a result, the memory cell may be programmed using a lower voltage or lower programming time to achieve a defined cell current corresponding to a programmed state. Thus, embodiments of the invention may increase the operational efficiency of the memory cell.

One embodiment provides a method of forming a split-gate flash memory cell, including: forming a pair of gate structures over a substrate; performing a source implant between the pair of gate structures to form a self-aligned source implant region in the substrate; performing a field enhancement implant process to form field enhancement implant regions adjacent lateral edges of the source implant region, wherein the field enhanced implant has an opposite dopant polarity as the source implant; and performing an anneal to diffuse the source implant region and field enhancement implant regions, to thereby define a source region with field enhanced regions at lateral edges of the source region.

In some embodiments, the field enhanced implant process is performed after the source implant. In other embodiments, the field enhanced implant process is performed before the source implant.

In some embodiments, the field enhanced implant process includes at least one non-vertical implant with respect to a top surface of the substrate. For example, the field enhanced implant process may include multiple implants at multiple different non-vertical angles, e.g., in two generally opposing directions, or in four directions offset 90 degrees from each other with respect to a vertical axis.

In some embodiments, the source implant comprises phosphorus or arsenic, and the field enhanced implant comprises boron. In some embodiments, the substrate is doped with boron, and wherein the field enhanced implant comprises boron and increases the boron concentration of the field enhancement implant regions of the substrate.

In some embodiments, the field enhanced regions at the lateral edges of the source region provide a reduced programming voltage or time to achieve a target cell current, as compared with a cell without field enhanced junctions.

Another embodiment provides a split-gate flash memory cell including a substrate, a pair of floating gates formed over the substrate, a doped source region in the substrate, and doped field enhancement regions in the substrate adjacent lateral edges of the source region, wherein the field enhancement regions have an opposite dopant polarity as the source region. The split-gate flash memory cell may also include wordlines formed the floating gates, and bitlines laterally spaced apart from the source region.

In some embodiments, the field enhanced regions in the substrate provide a reduced programming voltage or time to achieve a target cell current for the memory cell, as compared with a memory cell without field enhanced regions.

In some embodiments, the source implant comprises phosphorus or arsenic, and the field enhanced implant comprises boron. In some embodiments, the substrate is doped with boron, and wherein the field enhanced implant comprises boron and increases the boron concentration of the field enhancement implant regions of the substrate.

In some embodiments, the split-gate flash memory cell comprises a SuperFlash memory cell by Microchip Technology Inc., having a location at 2355 W Chandler Blvd, Chandler, Ariz. 85224.

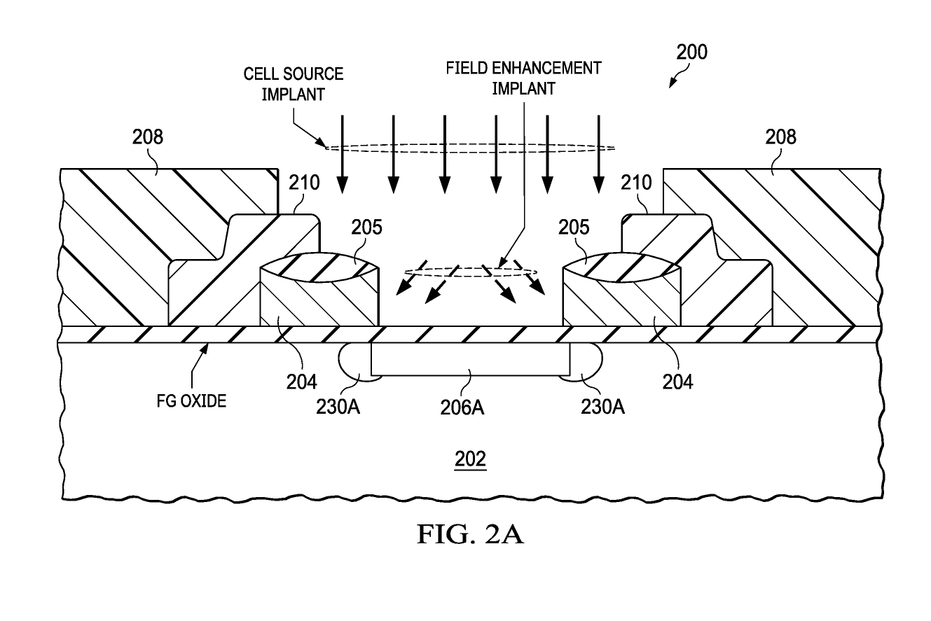

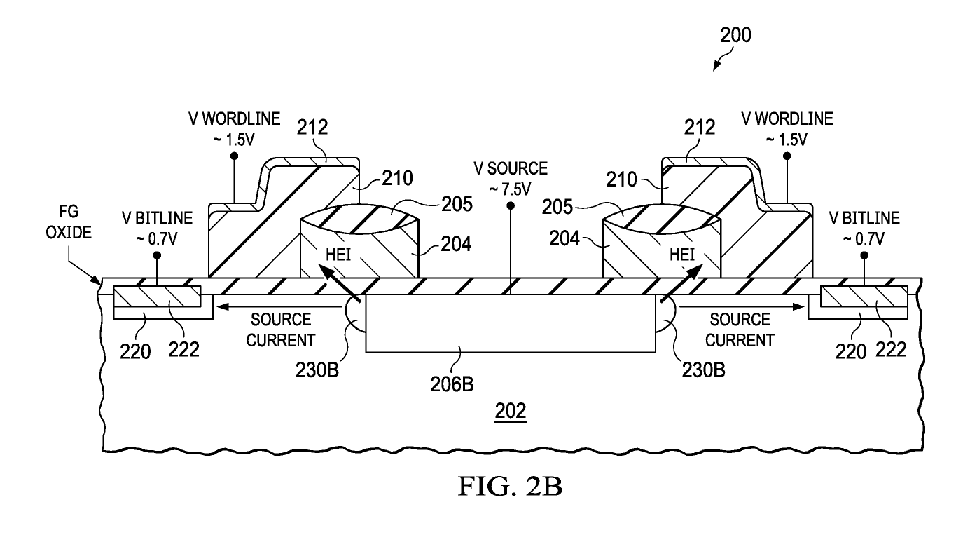

FIG. 2A illustrates a source implant for an example split-gate flash memory cell, along with field enhancement implants that form field enhancement implant regions near lateral edges of the source implant region in the substrate, according to an example embodiment of the present invention.

FIG. 2A illustrates a structure 200 of a partially formed split-gate flash memory cell, according to an embodiment of the present invention. As shown, a pair of floating gates 204 having football-shaped oxide regions 205 are formed over a substrate 202, and a Poly2 wordline 210 may be formed over each floating gate 204. A vertical source implant is performed between the floating gates 204, to define a source implant region 206A having self-aligned edge junctions. In some embodiments, the source implant may comprise phosphorous, arsenic, or other n-type dopant.

In addition to the source implant, a field enhancement implant process is performed to form field enhancement implant regions 230A proximate the lateral edges of the source implant region in the substrate. The field enhancement implant process may include one or multiple field enhancement implants performed at one or more non-vertical angles with respect to the top surface of the substrate. For example, as shown in FIG. 2A, the field enhanced implant process may include two non-vertical implants delivered in generally opposing directions, as indicated by the angled arrows in opposing directions. As another example, the field enhanced implant process may include four non-vertical implants along four directions offset 90 degrees from each other with respect to a vertical axis (e.g., the two non-vertical implant directions shown in FIG. 2A, along with a pair of non-vertical implant directions perpendicular to the two illustrated implant directions). The physical structure of each floating gate may act as mask to align and delimit the specific location of each non-vertical field enhancement implants, e.g., to prevent each field enhancement implant from extending laterally too far under the respective floating gate (e.g., too close to the adjacent bitline).

In some embodiments, the field enhanced implant process may include at least one implant delivered at an angle of at least 5 degrees with respect to vertical, at least 10 degrees with respect to vertical, at least 10 degrees with respect to vertical, at least 15 degrees with respect to vertical, at least 20 degrees with respect to vertical, at least 25 degrees with respect to vertical, at least 30 degrees with respect to vertical, at least 35 degrees with respect to vertical, at least 40 degrees with respect to vertical, at least 45 degrees with respect to vertical, at least 50 degrees with respect to vertical, at least 55 degrees with respect to vertical, or at least 60 degrees with respect to vertical, depending on the specific embodiment.

In some embodiments, the field enhanced implant process may include at least one implant delivered at an angle of between 5-70 degrees with respect to vertical, between 10-70 degrees with respect to vertical, between 15-70 degrees with respect to vertical, between 20-70 degrees with respect to vertical, between 25-70 degrees with respect to vertical, between 30-70 degrees with respect to vertical, between 35-70 degrees with respect to vertical, between 40-70 degrees with respect to vertical, between 45-70 degrees with respect to vertical, between 50-70 degrees with respect to vertical, between 55-70 degrees with respect to vertical, or between 60-70 degrees with respect to vertical, depending on the specific embodiment.

As noted above, each field enhancement implant 230A may comprise boron or other suitable p-type implant. The field enhancement implant(s) 230A may increase the existing dopant concentration of the substrate 202, which may be doped with boron or other p-type dopant prior to the field enhancement implants.

FIG. 2B illustrates the example split-gate flash memory cell structure 200 of FIG. 2A, after performing an anneal process that causes a diffusion of the source implant region 206A and field enhancement implant regions 230A in the substrate 202, to define the final source region 206B with field-enhanced edge junctions 230B, as shown. The field enhancement implant(s) may be specifically angled (during the implant shown in FIG. 2A) to maximize the post-diffusion field 206B at the source implant edge. The formation of the memory cell may be further completed, e.g., including forming bitline junctions 220 and corresponding bitline contacts 222, along with wordline contacts 212 over the Poly2 wordlines 210.

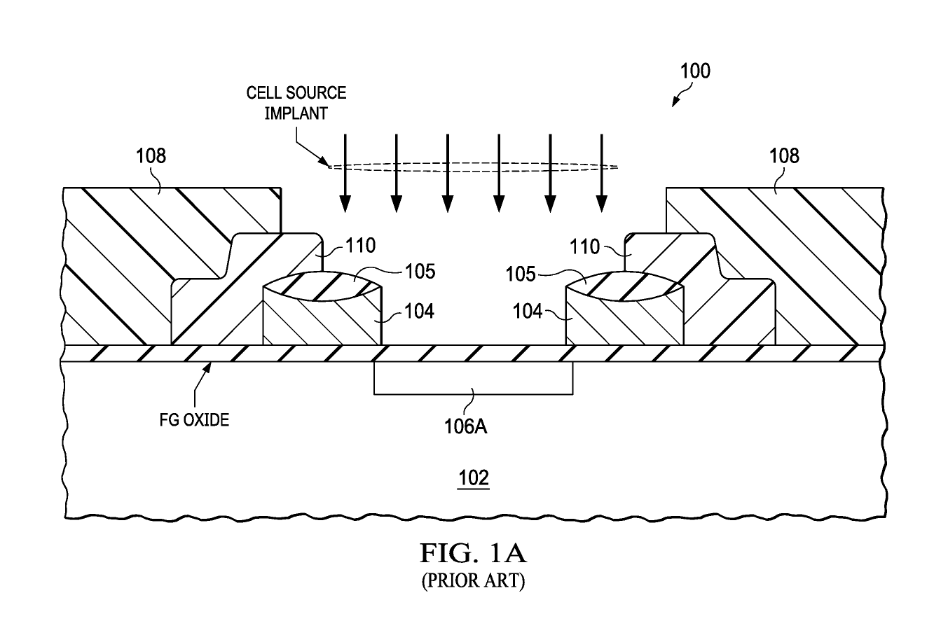

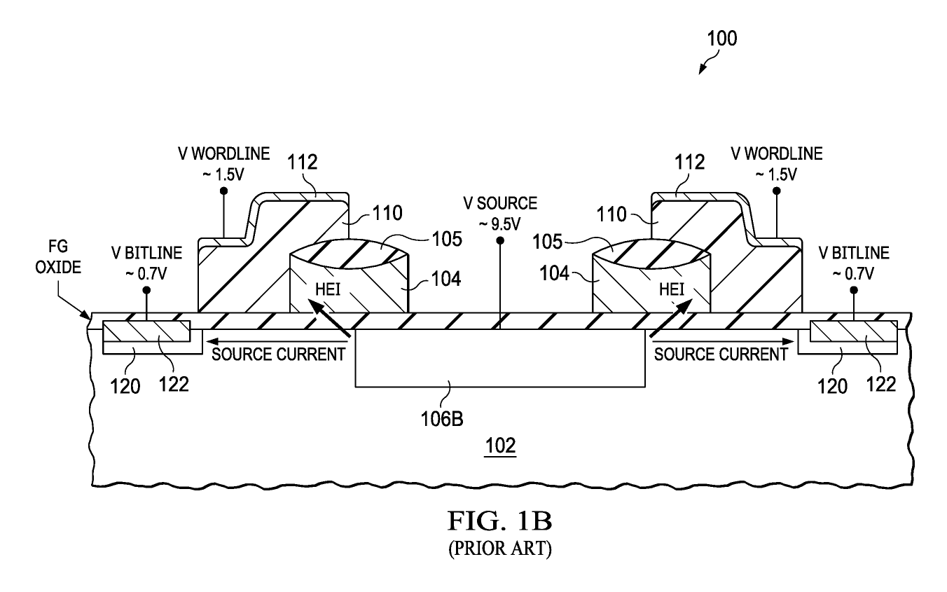

As discussed above, the field-enhanced regions 230B may increase the p-type dopant concentration in the substrate 202 proximate the lateral edges of the n-type source region 206B, which defines a more abrupt or acute junction between the p-type source region 206B and adjacent n-type substrate 202 (specifically, the field-enhanced regions 230B of the substrate), which increases the field energy resulting from a particular voltage (as compared with a conventional cell without the field-enhanced implants disclosed herein). As a result, the memory cell 200 shown in FIG. 2B may be programmed, via hot electron injection (HEI), using a lower voltage or lower programming time to achieve a defined cell current corresponding to a programmed state, as compared with a conventional memory cell (e.g., the cell shown in FIG. 1B). In other words, for a given programming threshold (e.g., a current of 1.0 μA between the source and drain may define whether the cell has a programmed (1) or erased (0) state), a lower source programming voltage can be used for the same programming time, or alternatively a lower programming time may be used for a given programming voltage.

For example, as shown in FIG. 2B, a voltage of ˜7.5V is applied to the source region 206B for a defined time to achieve a threshold cell current corresponding with a programmed state, as compared with the voltage of ˜9.5V required for programming the conventional cell 100 shown in FIG. 1B. Thus, the invention increases the operational efficiency of the memory cell.

In addition, by providing a more abrupt or acute junction between the source region 230B and neighboring substrate 202 (specifically, the field-enhanced regions 230B of the substrate), the source implant dose/energy can be reduced while still providing the same field energy, as compared with a conventional design. Reducing the source implant dose/energy allows the lateral width of each floating gate to be reduced, to thereby reduce the footprint of the memory cell. The improved programming efficiency achieved through the use of the field enhancement implant(s) can be traded off with the lower field at a lower source implant dose. Because the lateral diffusion of the source implant defines the net floating gate length (for a programmed off-state cell), a scaled down cell can be more readily achieved.

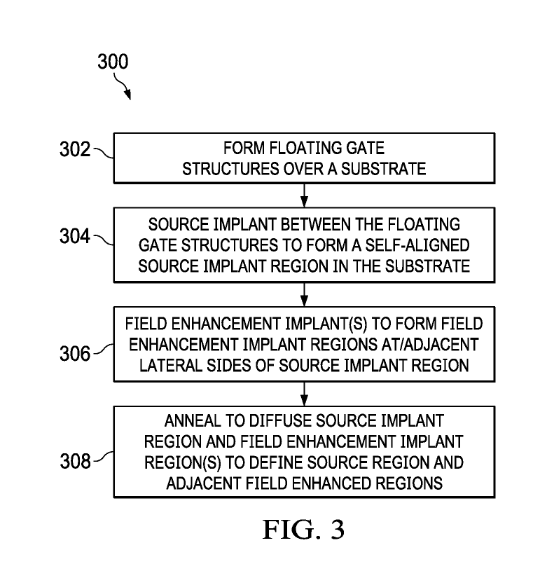

FIG. 3 illustrates an example process flow 300 for producing a split-gate flash memory cell, e.g., the example cell 200 shown in FIGS. 2A-2B, according to an example embodiment of the present invention. At 302, a pair of floating gate structures, including a poly FG structure and an overlying oxide region (e.g., football oxide) are formed over a substrate. At 304, a source implant, e.g., HVII implant of phosphorus or arsenic, is performed between the pair of floating gate structures to form a self-aligned source implant region in the substrate.

At 306, a field enhancement implant process is performed to form field enhancement implant regions at or adjacent lateral sides of the source implant region in the substrate. In some embodiments, step 306 (field enhancement implant process) is performed after step 304 (source implant). In other embodiments, step 306 (field enhancement implant process) is performed during or after step 304 (source implant). In some embodiments, the field enhanced implant process at 306 includes at least one non-vertical implant with respect to a top surface of the substrate. For example, step 306 may include multiple implants at multiple different non-vertical angles. In some embodiments, the field enhanced implant comprises boron or other suitable material(s). In some embodiments, the substrate is doped with boron, and the field enhanced implant comprises boron and increases the boron concentration of the field enhancement implant regions of the substrate.

At 308, an anneal may be performed to diffuse the source implant region and field enhancement implant regions, to thereby define a source region and field enhanced regions at lateral edges of the source region in the substrate, e.g., as shown in FIG. 2B.

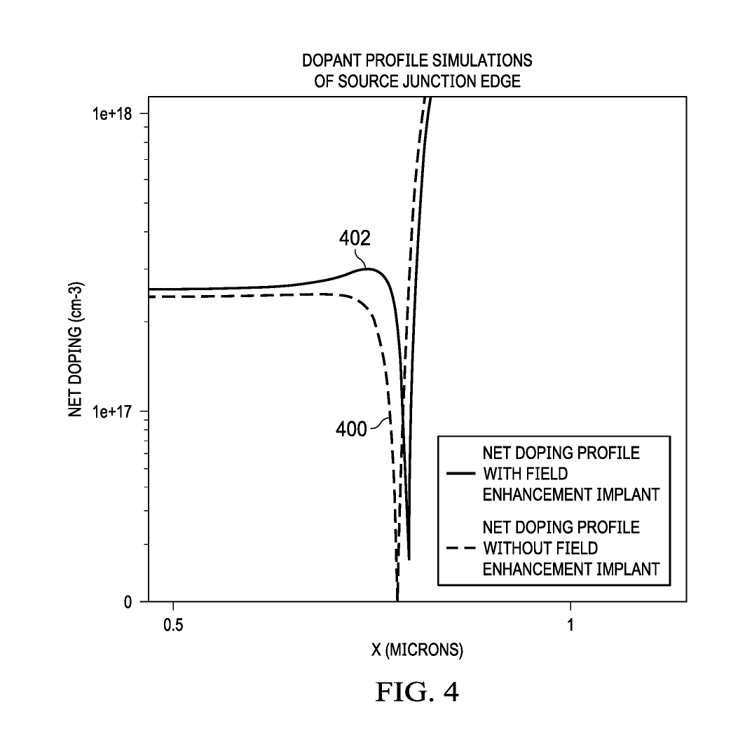

FIG. 4 illustrates example a net dopant profile simulation at the source junction edge for (a) a conventional memory cell, indicated by curve 400, and (b) a memory cell formed according to an embodiment of the present invention (e.g., using field enhancement implants to provide field-enhanced source junction edges), indicated by curve 402. Each doping profile 400, 402 indicates a net doping concentration as a function of lateral position across an area transitioning from the substrate (left side of each profile), through a source edge junction, and into the source (right side of each profile), e.g., the area indicated in FIG. 2B as “Doping Transition Area.”

The exact point of the n-p junction is indicated by the bottom tip of the downward spike in each profile 400, 402. The portion of each profile 400, 402 left of the junction represents the p-type dopant concentration (e.g., boron) in the respective cell substrate, while the portion of each profile left of the junction represents the n-type dopant concentration (e.g., phosphorous) in the respective source region.

As shown, the example dopant profile 402 for the memory cell including field enhancement implants has an upward “bump” corresponding with the respective field enhancement implant (e.g., implant 230B shown in FIG. 2B). Further, the downward spike in the example dopant profile 402 for the memory cell including field enhancement implants is more compressed, with respect to the lateral position, than the dopant profile 400 for the conventional cell, which indicates the more abrupt or acute junction between the p-type source region and adjacent n-type substrate in the memory cell according to the present invention, e.g., cell 200 shown in FIG. 2B.

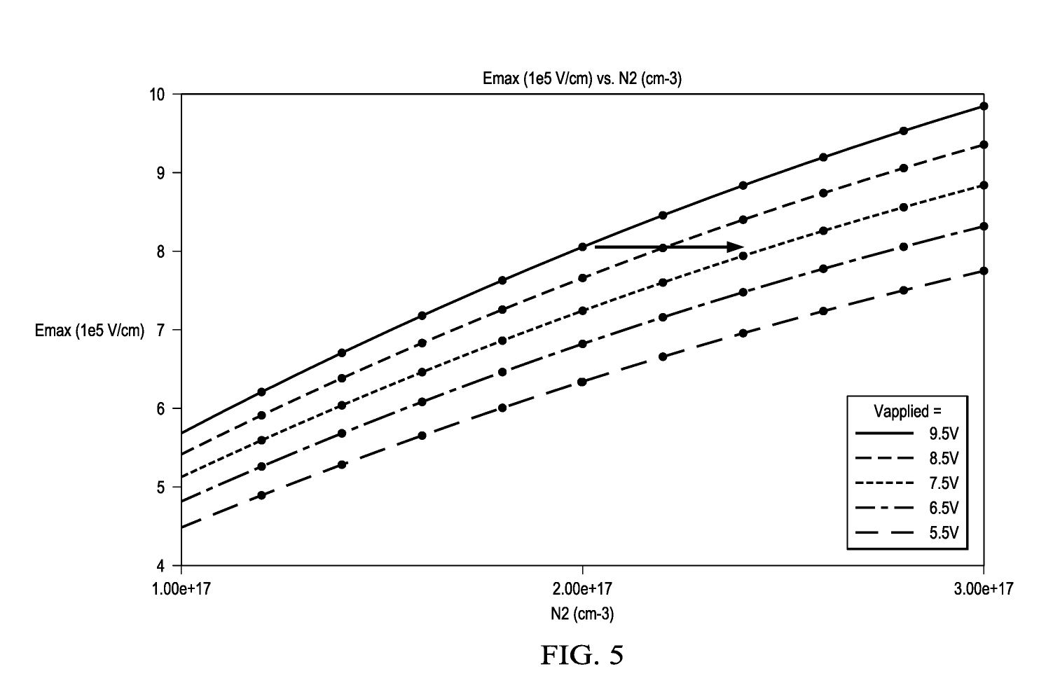

FIG. 5 shows a graph illustrating the relationship between field junction doping concentration (e.g., substrate doping concentration at the source edge junction) and resulting electric field in a memory cell, for various example program voltage levels applied to the cell. As indicated by the horizontal arrow in FIG. 5, by increasing the junction doping from 2.0e+17 to 2.4e+17, the program voltage required to achieve a defined electric field may be reduced from ˜9.5V to ˜7.5V. Thus, FIG. 5 illustrates that an increase in field junction doping concentration allows a reduction in the required program voltage for the cell.

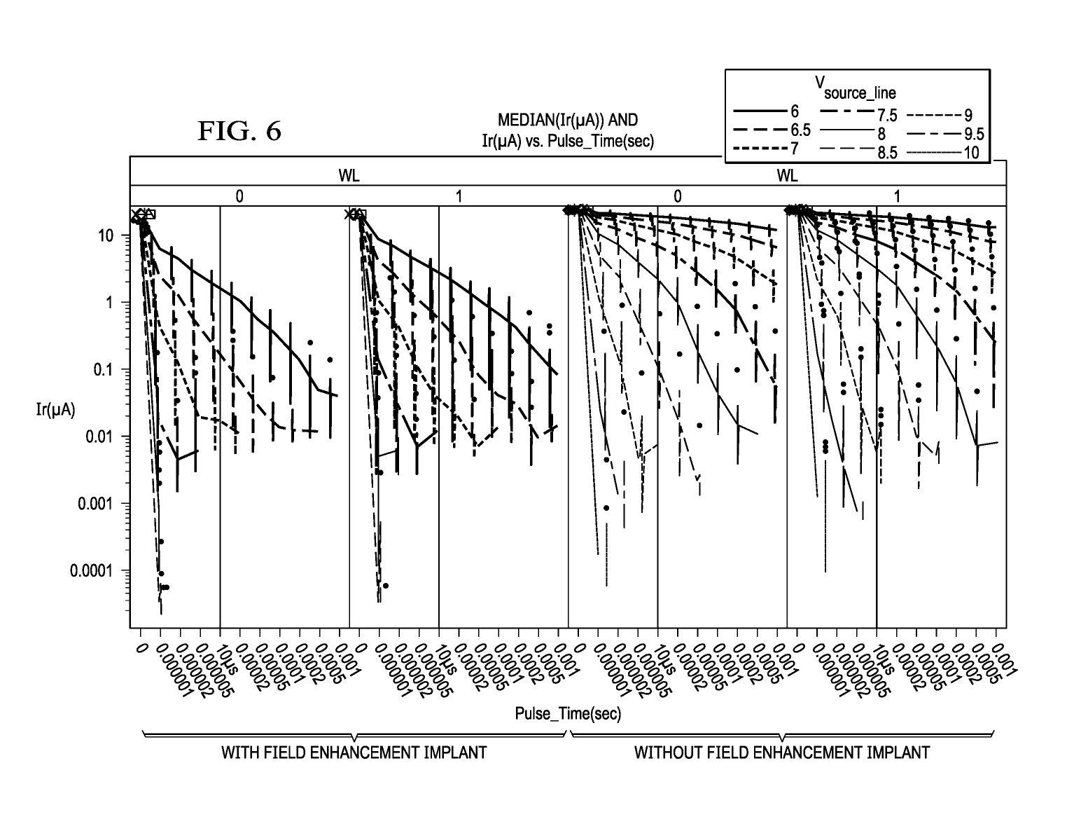

FIG. 6 illustrates example graphs of programming time versus resulting cell current for (a) a pair of bit cells of an example split-gate memory cell formed with field enhancement implants according to the present invention (e.g., as shown in FIG. 2B) and (b) a pair of bit cells of a conventional split-gate memory cell without field enhancement implants (e.g., as shown in FIG. 1B). Each of the four graphs plots multiple different lines, each corresponding to a different program voltage. As shown, the memory cell formed according to the present invention allows a reduced programming time to achieve a defined cell current (e.g., indicated by either of the horizontal lines running though the graph).

1. A method of forming a split-gate memory cell, the method comprising:
forming a pair of floating gate structures over a substrate;
performing a source implant between the pair of floating gate structures to form a self-aligned source implant region in the substrate;
performing a field enhancement implant process to form field enhancement implant regions at or adjacent lateral sides of the source implant region and extending at least partially under each of the pair of floating gate structures; and
performing an anneal to diffuse the source implant region and field enhancement implant regions laterally such that each field enhancement implant region diffuses further under a respective floating gate in a lateral direction, to thereby define a source region with field enhanced regions at lateral edges of the source region and underneath the pair of floating gates, wherein the field enhanced regions underneath the pair of floating gates increase a programming efficiency for programming the memory cell via hot electron injection.

2. The method of claim 1, wherein the field enhanced implant has an opposite dopant polarity as the source implant.

3. The method of claim 1, wherein the field enhanced implant process is performed after the source implant.

4. The method of claim 1, wherein the field enhanced implant process is performed before the source implant.

5. The method of claim 1, wherein the field enhanced implant process includes at least one non-vertical implant with respect to a top surface of the substrate.

6. The method of claim 1, wherein the field enhanced implant process includes multiple implants at multiple different non-vertical angles.

7. The method of claim 1, wherein the source implant comprises phosphorus or arsenic, and the field enhanced implant comprises boron.

8. The method of claim 1, wherein the substrate is doped with boron, and wherein the field enhanced implant comprises boron and increases the boron concentration of the field enhancement implant regions of the substrate.

9. The method of claim 1, wherein the field enhanced regions at the lateral edges of the source region provide a reduced programming voltage or time to achieve a target cell current, as compared with a cell without field enhanced junctions.

10. The method of claim 1, wherein the split-gate memory cell comprises a split-gate flash memory cell.

11. The method of claim 1, wherein the split-gate memory cell comprises a SuperFlash 1, SuperFlash 2, or SuperFlash 3 memory cell.

12. A split-gate memory cell, comprising:
a substrate;
a pair of floating gates formed over the substrate;
a doped source region in the substrate having lateral edges located underneath each of the pair of floating gates; and
doped field enhancement regions in the substrate laterally adjacent the lateral edges of the source region and underneath each of the pair of floating gates;
wherein the field enhancement regions located underneath the pair of floating gates have an opposite dopant polarity as the source region to thereby increase a programming efficiency for programming the memory cell via hot electron injection.

13. The memory cell of claim 12, wherein the field enhanced regions in the substrate provide a reduced programming voltage or time to achieve a target cell current for the memory cell, as compared with a memory cell without field enhanced regions.

14. The memory cell of claim 12, wherein the source implant comprises phosphorus or arsenic, and the field enhanced implant comprises boron.

15. The memory cell of claim 12, wherein the substrate is doped with boron, and wherein the field enhanced implant comprises boron and increases the boron concentration of the field enhancement implant regions of the substrate.

16. The memory cell of claim 12, wherein the memory cell is a split-gate flash memory cell.

17. The memory cell of claim 12, further comprising wordlines formed the floating gates, and bitlines laterally spaced apart from the source region.

18. The memory cell of claim 12, wherein the split-gate memory cell comprises a SuperFlash 1, SuperFlash 2, or SuperFlash 3 memory cell.

19. The memory cell of claim 12, comprising a respective wordline formed over each of the pair of floating gates.

20. The method of claim 1, comprising:
forming a wordline over each of the pair of floating gates;
wherein performing the anneal causes each field enhancement implant region to diffuse lateral toward a respect one of the wordlines.
